(19) United States
(12) Patent Application Publication
(10) Pub. No.: US 2025/0072003 A1
(43) Pub. Date: Feb. 27, 2025

(54) SEMICONDUCTOR DEVICE INCLUDING FERROELECTRIC CAPACITOR AND METHOD FOR MANUFACTURING THE SAME

(71) Applicant: TAIWAN SEMICONDUCTOR MANUFACTURING COMPANY, LTD., Hsinchu (TW)

(72) Inventors: Tzu-Yu CHEN, Hsinchu (TW); Chu-Jie HUANG, Hsinchu (TW); Yu-Wen LIAO, Hsinchu (TW); Sheng-Hung SHIH, Hsinchu (TW); Kuo-Chi TU, Hsinchu (TW)

(73) Assignee: TAIWAN SEMICONDUCTOR MANUFACTURING COMPANY, LTD., Hsinchu (TW)

(21) Appl. No.: 18/454,128

(22) Filed: Aug. 23, 2023

(51) Int. Cl. H10B 53/30; H01L 21/768; H01L 23/522

(52) U.S. Cl. CPC H10B 53/30; H01L 21/76802; H01L 21/76832; H01L 21/7684; H01L 21/76841; H01L 23/5226

(57) ABSTRACT

A method for manufacturing a semiconductor device includes: forming an etch stop layer with an opening; forming a barrier layer on the etch stop layer to fill the opening, the barrier layer including a layer portion disposed on the etch stop layer and an insert portion protruding from the layer portion to be inserted into the opening of the etch stop layer; forming a bottom electrode layer on the layer portion of the barrier layer opposite to the etch stop layer; forming a ferroelectric layer on the bottom electrode layer opposite to the barrier layer; and forming a top electrode layer on the ferroelectric layer opposite to the bottom electrode layer.

### BACKGROUND

In recent years, there is an increased demand of semiconductor memory devices. A ferroelectric tunnel junction (FTJ) memory device is a promising semiconductor memory device due to its advantages, such as low power usage, fast write performance, and great data retention. In order to reduce a manufacturing cost for manufacturing the FTJ memory device, the semiconductor industry strives to simplify a manufacturing process for the FTJ memory device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are flow diagrams illustrating a method for manufacturing a semiconductor device in accordance with some embodiments.

FIGS. 2 to 17 are schematic views illustrating some intermediate stages of the method as depicted in FIGS. 1A and 1B in accordance with some embodiments.

FIG. 18 is a schematic view illustrating a semiconductor device in accordance with some embodiments.

FIG. 19 is a schematic view illustrating a semiconductor device in accordance with some embodiments.

FIGS. 20 to 22 are schematic views illustrating some intermediate stages of a method for manufacturing a semiconductor structure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “upper,” “lower,” “topmost” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

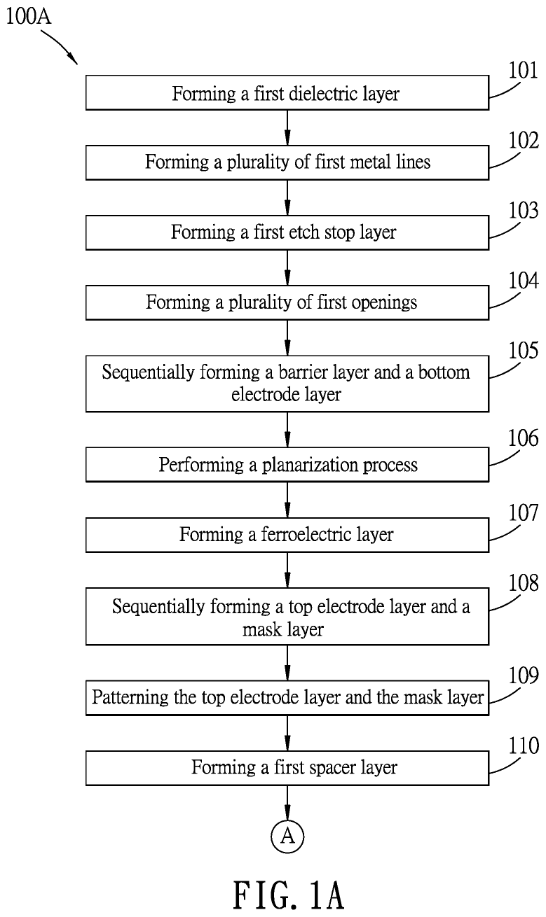

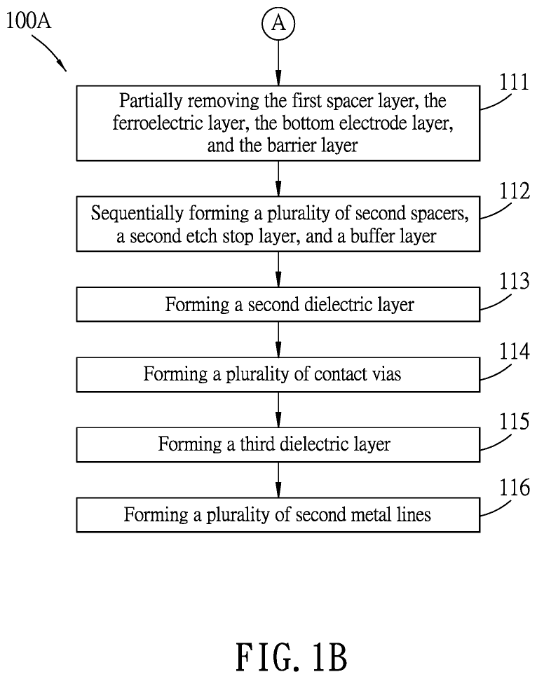

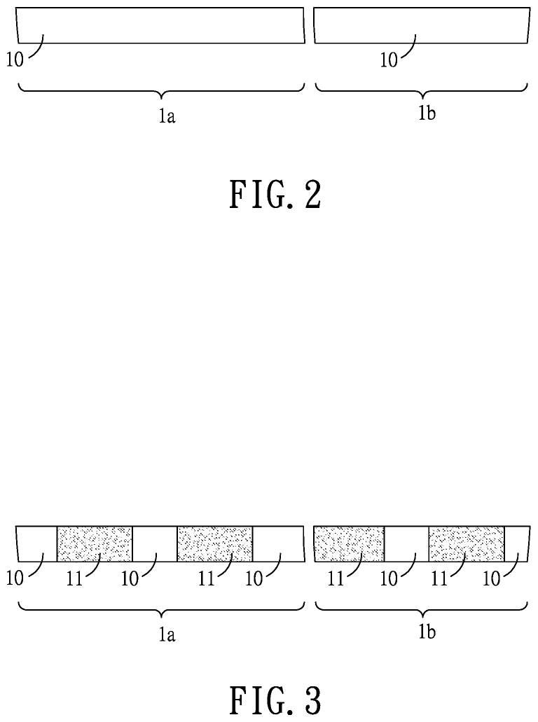

The present disclosure is directed to a semiconductor device including a ferroelectric capacitor and a method for manufacturing the same. FIGS. 1A and 1B are flow diagrams illustrating a method 100A for manufacturing a semiconductor device 200A shown in FIG. 17 in accordance with some embodiments. FIGS. 2 to 16 illustrate schematic views of some intermediate stages of the method 100A. Some portions may be omitted in FIGS. 2 to 16 for the sake of brevity. Additional steps can be provided before, after or during the method 100A, and some of the steps described herein may be replaced by other steps or be eliminated.

Referring to FIG. 1A and the example illustrated in FIG. 2, the method 100A begins at step 101, where a first dielectric layer 10 is formed. In some embodiments, the first dielectric layer 10 is formed on a topmost dielectric layer of an interconnect structure (not shown) disposed on a semiconductor substrate (not shown). In some embodiments, the interconnect structure includes a plurality of contact vias (not shown) that are disposed in the topmost dielectric layer and that are spaced apart from each other. The first dielectric layer 10 may include, for example, but not limited to, silicon oxide, silicon nitride, silicon carbide, silicon oxycarbide, silicon oxynitride, silicon carbonitride, silicon oxycarbonitride, undoped silicate glass (USG), phosphosilicate glass (PSG), borosilicate glass (BSG), boron-doped phosphosilicate glass (BPSG), fluorine-doped silicate glass (FSG), or combinations thereof. In alternative embodiments, the first dielectric layer 10 may include, for example, but not limited to, polyimide, epoxy resin, acrylic resin, phenol resin, benzocyclobutene (BCB), polybenzooxazole (PBO), other suitable polymer-based dielectric materials, or combinations thereof. Other suitable materials for the first dielectric layer 10 are within the contemplated scope of the present disclosure. The first dielectric layer 10 may be formed by a suitable deposition process, for example, but not limited to, chemical vapor deposition (CVD), physical vapor deposition (PVD), or other suitable deposition processes. In some embodiments, the first dielectric layer 10 may include a device memory region 1a and a device peripheral region 1b. In some embodiments, the first dielectric layer 10 may be an interlayer dielectric (ILD) layer.

Referring to FIG. 1A and the example illustrated in FIG. 3, the method 100A then proceeds to step 102, where a plurality of first metal lines 11 are formed in the first dielectric layer 10. Step 102 may include sub-steps: (i) patterning the first dielectric layer 10 to form a plurality of first recesses (not shown), (ii) depositing a metallic material on the first dielectric layer 10 to fill the first recesses, and (iii) removing excess of the metallic material on the first dielectric layer 10, so as to form the first metal lines 11.

In sub-step (i), the first dielectric layer 10 may be patterned by photolithography, which includes an etching processes. The photolithography may include, for example, but not limited to, coating a photoresist on the first dielectric layer 10, soft-baking the photoresist, exposing the photoresist through a photomask, post-exposure baking the photoresist, and developing the photoresist, followed by hard-baking the photoresist so as to form a patterned photoresist on the first dielectric layer 10. In the etching process, the first dielectric layer 10 may be etched by a suitable etching process, for example, but not limited to, dry etching, wet etching, a combination thereof, or other suitable etching processes, so as to form the first recesses.

In sub-step (ii), the metallic material may be deposited by a suitable deposition process, for example, but not limited to, CVD, PVD, electroless plating, electroplating, or other suitable deposition processes.

In sub-step (iii), removal of excess of the metallic material on the first dielectric layer 10 may be performed by a suitable planarization process, for example, but not limited to, chemical mechanical polishing (CMP) or other suitable planarization processes. The metallic material for forming the first metal lines 11 may include, for example, but not limited to, copper, aluminum, tungsten, or combinations thereof. Other suitable materials for the first metal lines 11 are within the contemplated scope of the present disclosure.

In some embodiments, one or more of the first metal lines 11 are in contact with corresponding one(s) of the contact vias of the interconnect structure, respectively.

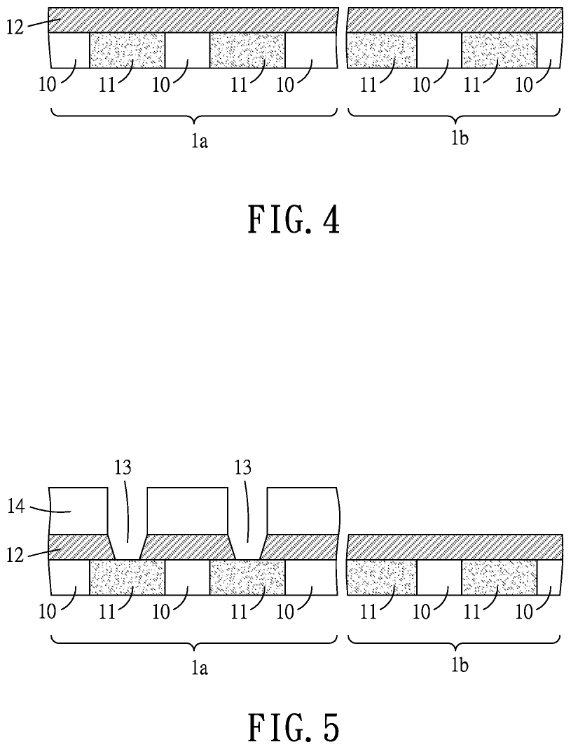

Referring to FIG. 1A and the example illustrated in FIG. 4, the method 100A then proceeds to step 103, where a first etch stop layer 12 is formed on the first dielectric layer 10 and the first metal lines 11. The first etch stop layer 12 may include, for example, but not limited to, metal nitride, metal oxide, metal carbide, silicon nitride, silicon oxide, silicon carbide, silicon oxynitride, or combinations thereof. Other suitable materials for the first etch stop layer 12 are within the contemplated scope of the present disclosure. The first etch stop layer 12 may be formed by a suitable deposition process, for example, but not limited to, CVD, plasma-enhanced CVD (PECVD), atomic layer deposition (ALD), spin-on coating, electroless plating, or other suitable deposition processes. In some embodiments, in this step, after formation of the first etch stop layer 12, a top surface of the first etch stop layer 12 may be planarized by a suitable planarization process (e.g., CMP or other suitable planarization processes).

Referring to FIG. 1A and the example illustrated in FIG. 5, the method 100A then proceeds to step 104, where a plurality of first openings 13 are formed in the first etch stop layer 12 in the device memory region 1a, so as to expose the first metal lines 11 in the device memory region 1a. Step 104 may be performed by patterning the first etch stop layer 12 using a patterned photoresist layer 14 so as to form the first openings 13. The patterning process may be a photolithography process as described above in step 102, and details thereof are omitted for the sake of brevity. After this step, the patterned photoresist layer 14 is removed by, for example, but not limited to, an ashing process.

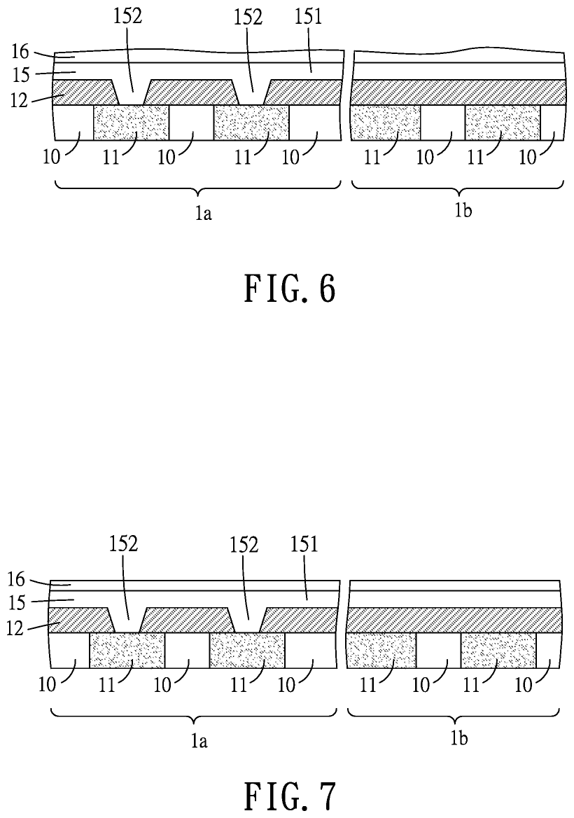

Referring to FIG. 1A and the example illustrated in FIG. 6, the method 100A then proceeds to step 105, where a barrier layer 15 and a bottom electrode layer 16 are sequentially formed on the structure shown in FIG. 5. Step 105 may be performed by depositing a barrier material layer for the barrier layer 15 on the structure shown in FIG. 5, followed by depositing an electrode material layer for the bottom electrode layer 16 on the barrier material layer.

The barrier material layer for the barrier layer 15 is deposited on the top surface of the first etch stop layer 12 and fills the first openings 13 (see FIG. 5) by a suitable deposition process, for example, but not limited to, CVD, metal organic chemical vapor deposition (MOCVD), PVD, ALD, or other suitable deposition processes. The barrier material layer for the barrier layer 15 may include, for example, but not limited to, titanium nitride, platinum, aluminum copper, gold, titanium, tantalum, tantalum nitride, tungsten, tungsten nitride, alloys thereof, or combinations thereof. Other suitable materials for the barrier layer 15 are within the contemplated scope of the present disclosure. The barrier layer 15 is in direct contact with the first metal lines 11 in the first openings 13. The barrier layer 15 includes a layer portion 151 disposed on the first etch stop layer 12 and a plurality of insert portions 152 formed integrally with the layer portion 151. The layer portion 151 has an upper flat surface. Each of the insert portions 152 protrudes downwardly from the layer portion 151 and is inserted into a corresponding one of the first openings 13 in the first etch stop layer 12.

In some embodiments, the first etch stop layer 12 has an upper surface in contact with the layer portion 151 of the barrier layer 15 and a lower surface opposite to the upper surface. In some embodiments, each of the insert portions 152 of the barrier layer 15 is formed with a tapered configuration which is tapered in a direction from the upper surface of the first etch stop layer 12 to the lower surface of the first etch stop layer 12. In some embodiments, each of the first openings 13 has a dimension decreasing gradually in a direction from the upper surface of the first etch stop layer 12 to the lower surface of the first etch stop layer 12, such that a corresponding one of the insert portion 152 of the barrier layer 15 is formed with the tapered configuration.

The electrode material layer for the bottom electrode layer 16 is deposited on the barrier layer 15 by a suitable deposition process, for example, but not limited to, CVD, PVD, ALD, or other suitable deposition processes. The electrode material layer for the bottom electrode layer 16 may include, for example, but not limited to, titanium nitride, platinum, aluminum copper, gold, titanium, tantalum, tantalum nitride, tungsten, tungsten nitride, alloys thereof, or combinations thereof. Other suitable materials for the bottom electrode layer 16 are within the contemplated scope of the present disclosure. The bottom electrode layer 16 is electrically connected to the first metal lines 11 through the barrier layer 15. In some embodiments, the bottom electrode layer 16 and the barrier layer 15 may be made of different materials.

Referring to FIG. 1A and the example illustrated in FIG. 7, the method 100A then proceeds to step 106, where a planarization process (e.g., CMP or other suitable planarization processes) is performed on the structure shown in FIG. 6 to remove an excess portion of the bottom electrode layer 16. After this step, the bottom electrode layer 16 may have an upper flat surface, which is conducive to improving polarization of each of a plurality of ferroelectric elements 17′ (which will be described hereinafter in step 111), and to further enhancing the device performance of the semiconductor device 200A. In addition, the bottom electrode layer 16 has a lower flat surface in contact with the upper flat surface of the layer portion 151 of the barrier layer 15.

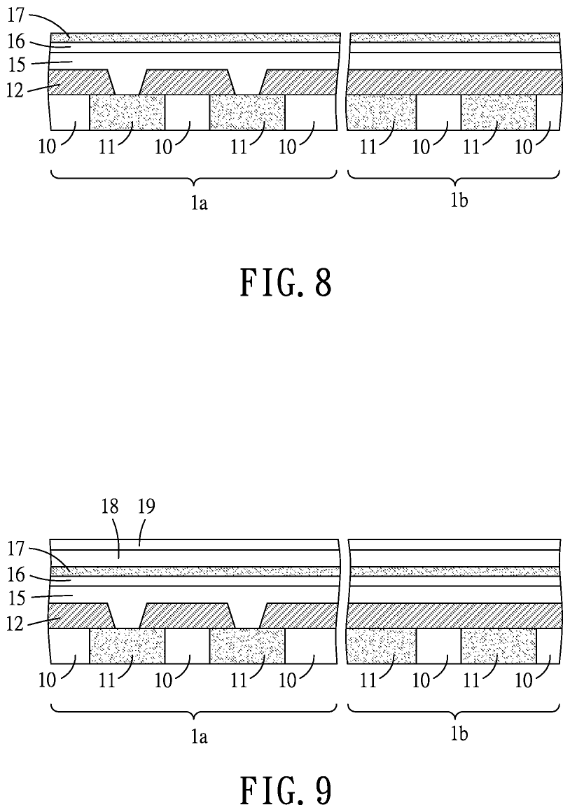

Referring to FIG. 1A and the example illustrated in FIG. 8, the method 100A then proceeds to step 107, where a ferroelectric layer 17 is formed on the bottom electrode layer 16 opposite to the barrier layer 15. The ferroelectric layer 17 may include a ferroelectric material, which may include binary oxides, ternary oxides, quaternary oxides, nitrides, or combinations thereof. The binary oxides may include, for example, but not limited to, hafnium oxide (hafnia, HfO₂) or other suitable materials. The ternary oxides may include, for example, but not limited to, hafnium silicate (HfSiOₓ), hafnium zirconate (HfZrOₓ), barium titanate (BaTiO₃), lead titanate (PbTiO₃), strontium titanate (SrTiO₃), calcium manganite (CaMnO₃), bismuth ferrite (BiFeO₃), doped HfO₂ (the dopants may include yttrium (Y), scandium (Sc), gallium (Ga), gadolinium (Gd), other suitable dopants, or combinations thereof), other suitable materials, or combinations thereof. The quaternary oxides may include, for example, but not limited to, lead zirconate titanate (PbZrₓTi_{y}O_{z}), barium strontium titanate (BaSrTiOₓ), strontium bismuth tantalate (SrBi₂Ta₂O₉), or combinations thereof. The nitrides may include, for example, but not limited to, aluminum scandium nitride (AlScN), aluminum gallium nitride (AlGaN), aluminum yttrium nitride (AlYN), or combinations thereof. Other suitable ferroelectric materials for the ferroelectric layer 17 are within the contemplated scope of the present disclosure. In some embodiments, the ferroelectric layer 17 may be formed by a suitable deposition process, for example, but not limited to, CVD, PVD, ALD, plasma-enhanced ALD, molecular beam epitaxy (MBE), or other suitable deposition processes. The ferroelectric layer 17 may be referred to as a ferroelectric tunnel junction (FTJ) layer. In some embodiments, the ferroelectric layer 17 may be formed as a single layer structure or a multi-layered structure. In some embodiments, when the ferroelectric layer 17 is formed as the multi-layered structure, the ferroelectric layer 17 may include a plurality of films made of different materials.

Referring to FIG. 1A and the example illustrated in FIG. 9, the method 100A then proceeds to step 108, where a top electrode layer 18 and a mask layer 19 are sequentially formed on the structure shown in FIG. 8. The top electrode layer 18 is formed on the ferroelectric layer 17 opposite to the bottom electrode layer 16. The material and process for forming the top electrode layer 18 may be the same as or similar to those for forming the bottom electrode layer 16, and thus details thereof are omitted for the sake of brevity. In some embodiments, the top electrode layer 18 may be formed as a single layer structure or a multi-layered structure. Similarly, the bottom electrode layer 16 may be formed as a single layer structure or a multi-layered structure. The mask layer 19 is formed on the top electrode layer 18 opposite to the ferroelectric layer 17. The mask layer 19 may include, for example, but not limited to, titanium nitride, silicon oxide, silicon nitride, silicon carbide nitride, silicon oxide nitride, metal oxide (e.g., titanium oxide, aluminum oxide or the like), or combinations thereof. Other suitable materials for the mask layer 19 are within the contemplated scope of the present disclosure. The mask layer 19 may be formed by a suitable deposition process, for example, but not limited to, CVD, PVD, ALD, or other suitable deposition processes.

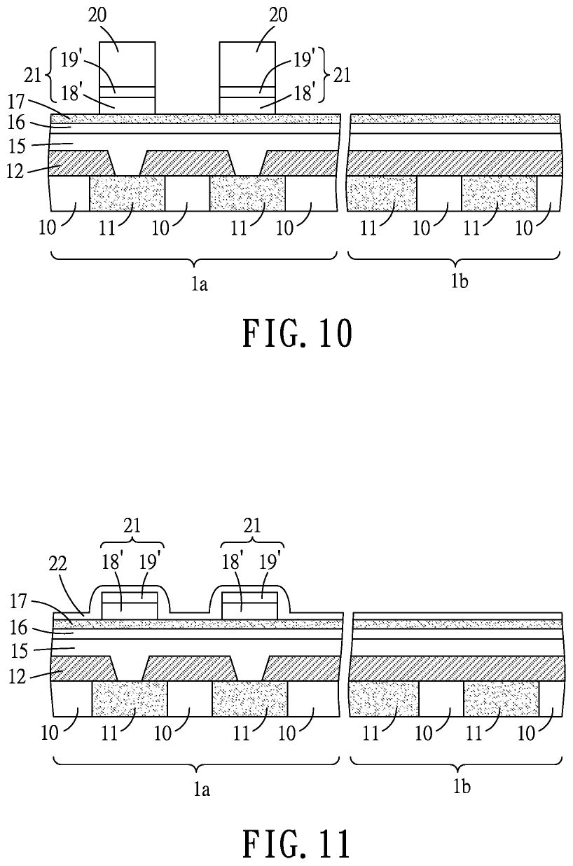

Referring to FIG. 1A and the example illustrated in FIG. 10, the method 100A then proceeds to step 109, where the top electrode layer 18 and the mask layer 19 shown in FIG. 9 are patterned to form a plurality of top electrodes 18′ and a plurality of masks 19′ in the device memory region 1a. Step 109 may be performed by photolithography (including an etching process) as described above in step 102, and thus details thereof are omitted for the sake of brevity. In this step, a patterned photoresist layer 20 is formed on the mask layer 19, and is used as a mask for etching the top electrode layer 18 and the mask layer 19 in the etching process. Each of the top electrodes 18′ and a corresponding one of the masks 19′ may be collectively referred to as a stack 21. In this step, some byproducts may be formed on lateral surfaces of the top electrodes 18′. After this step, the patterned photoresist layer 20 is removed by, for example, but not limited to, an ashing process.

Referring to FIG. 1A and the example illustrated in FIG. 11, the method 100A then proceeds to step 110, where a first spacer layer 22 is conformally formed on the structure shown in FIG. 10. The first spacer layer 22 may include, for example, but not limited to, silicon nitride, silicon oxide (SiOx), metal oxide, or combinations thereof. Other suitable materials for the first spacer layer 22 are within the contemplated scope of the present disclosure. The first spacer layer 22 may be formed by a suitable deposition process, for example, but not limited to, CVD, PVD, ALD, or other suitable deposition processes.

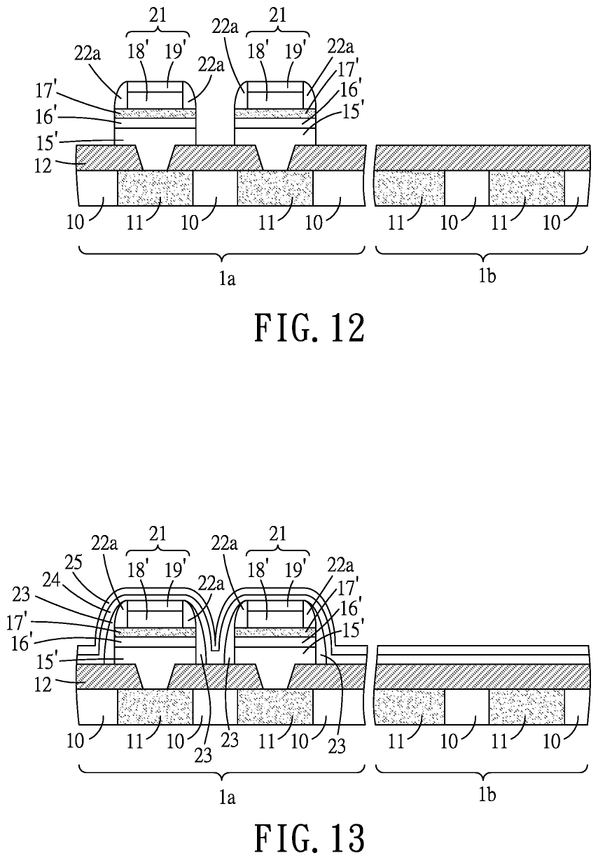

Referring to FIG. 1B and the example illustrated in FIG. 12, the method 100A then proceeds to step 111, where the first spacer layer 22, the ferroelectric layer 17, the bottom electrode layer 16, and the barrier layer 15 of the structure shown in FIG. 11 are partially removed. Step 111 may include sub-step (i) partially removing the first spacer layer 22 by photolithography, which includes an etching process, and sub-step (ii) partially removing the ferroelectric layer 17, the bottom electrode layer 16 and the barrier layer 15 by a suitable etching process.

In sub-step (i), a patterned photoresist layer (not shown) is formed on the first spacer layer 22 and is used as a mask for etching the first spacer layer 22 in the etching process or in a subsequent etching process in sub-step (ii). The etching process may be an anisotropically etching process (e.g., dry etching process or other suitable etching processes). After this step, the first spacer layer 22 is formed into a plurality of pairs of first spacers 22a. Each pair of the first spacers 22a are on the ferroelectric layer 17 to respectively cover two lateral sides of a corresponding one of the stacks 21.

In sub-step (ii), a portion of the ferroelectric layer 17, a portion of the bottom electrode layer 16, and a portion of the barrier layer 15 that are exposed from the stacks 21 are etched by a suitable etching process, for example, but not limited to, dry etching, wet etching, a combination thereof, or other suitable etching processes. After this sub-step, the ferroelectric layer 17 (see FIG. 11) is formed into the ferroelectric elements 17′ in the device memory region 1a, the bottom electrode layer 16 (see FIG. 11) is formed into a plurality of bottom electrodes 16′ in the device memory region 1a, and the barrier layer 15 (see FIG. 11) is formed into a plurality of barriers 15′ in the device memory region 1a. After this sub-step, the patterned photoresist layer is removed by, for example, but not limited to, an ashing process. The first spacers 22a may be used to cover the byproducts (if any, which may be formed in step 109) on the lateral surfaces of the top electrodes 18′, thereby avoiding formation of a shortcut between each of the top electrodes 18′ and a corresponding one of the bottom electrodes 16′ due to the presence of the byproducts.

Referring to FIG. 1B and the example illustrated in FIG. 13, the method 100A then proceeds to step 112, where a plurality of second spacers 23, a second etch stop layer 24, and a buffer layer 25 are sequentially formed on the structure shown in FIG. 12. Step 112 may include sub-steps (i) to (iii).

In sub-step (i), a second spacer layer (not shown) is conformally formed on the structure shown in FIG. 12, followed by conducting an etching process on the second spacer layer, so as to form the second spacers 23. The material and process for forming the second spacer layer may be the same as or similar to those for forming the first spacer layer 22, and thus details thereof are omitted for the sake of brevity. The etching process may be an anisotropically etching process (e.g., dry etching process or other suitable etching processes). After this sub-step, each pair of the second spacers 23 are respectively disposed on a corresponding pair of the first spacers 22a, two lateral sides of a corresponding one of the ferroelectric elements 17′, two lateral sides of a corresponding one of the bottom electrodes 16′, and two lateral sides of a corresponding one of the barriers 15′.

In sub-step (ii), the second etch stop layer 24 is formed on the first etch stop layer 12, the second spacers 23, and the masks 19′. The material and process for forming the second etch stop layer 24 may be the same as or similar to those for forming the first etch stop layer 12, and thus details thereof are omitted for the sake of brevity.

In sub-step (iii), the buffer layer 25 is formed on the second etch stop layer 24. In this sub-step, the buffer layer 25 may be formed by a suitable deposition process, for example, but not limited to, CVD, PECVD, or other suitable deposition processes. In some embodiments, the buffer layer 25 may be made of tetraethyl orthosilicate (TEOS). Other suitable materials for the buffer layer 25 are within the contemplated scope of the present disclosure.

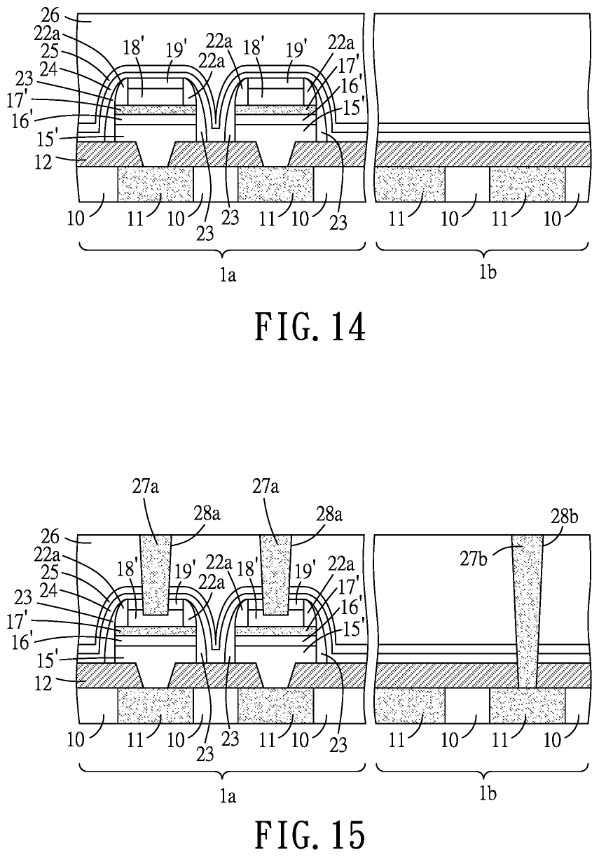

Referring to FIG. 1B and the example illustrated in FIG. 14, the method 100A then proceeds to step 113, where a second dielectric layer 26 is formed over the structure shown in FIG. 13. The material and process for forming the second dielectric layer 26 may be similar to or the same as those for forming the first dielectric layer 10, and thus details thereof are omitted for the sake of brevity. After this step, a planarization process (e.g., CMP or other suitable planarization process) may be performed to remove an excess portion of the second dielectric layer 26.

Referring to FIG. 1B and the example illustrated in FIG. 15, the method 100A then proceeds to step 114, where a plurality of contact vias 27a, 27b are formed in the second dielectric layer 26. Step 114 may include sub-steps (i) to (iii).

In sub-step (i), the second dielectric layer 26 is patterned by photolithography, so as to form a plurality of second openings 28a, 28b. Each of the second openings 28a penetrates the second dielectric layer 26, the buffer layer 25, the second etch stop layer 24 and a corresponding one of the masks 19′, and extends into a corresponding one of the top electrodes 18′ in the device memory region 1a. In some embodiments, each of the second openings 28a may penetrate the second dielectric layer 26, the buffer layer 25, the second etch stop layer 24 and the corresponding one of the masks 19′, and may terminate at an upper surface of the corresponding one of the top electrodes 18′ in the device memory region 1a. The second opening 28b penetrates the second dielectric layer 26, the buffer layer 25, the second etch stop layer 24 and the first etch stop layer 12 to expose a corresponding one of the first metal lines 11 in the device peripheral region 1b.

In sub-step (ii), a contact material for forming the contact vias 27a, 27b is deposited on the second dielectric layer 26 to fill the second openings 28a, 28b. The deposition of the contact material may be performed by a suitable deposition process, for example, but not limited to, CVD, PVD, electroless plating, electroplating, or other suitable deposition processes. The contact material may include, for example, but not limited to, copper, aluminum, tungsten, or combinations thereof. Other suitable materials for the contact vias 27a, 27b are within the contemplated scope of the present disclosure.

In sub-step (iii), an excess portion of the contact material on the second dielectric layer 26 is removed, so as to form the contact vias 27a, 27b. Removal of the excess portion of the contact material may be performed by a suitable planarization process, for example, but not limited to, CMP or other suitable planarization processes. The contact vias 27a filling the second openings 28a are electrically and respectively connected to the top electrodes 18′ in the device memory region 1a. The contact via 27b filling the second opening 28b is electrically and directly connected to a corresponding one of the first metal lines 11 in the device peripheral region 1b.

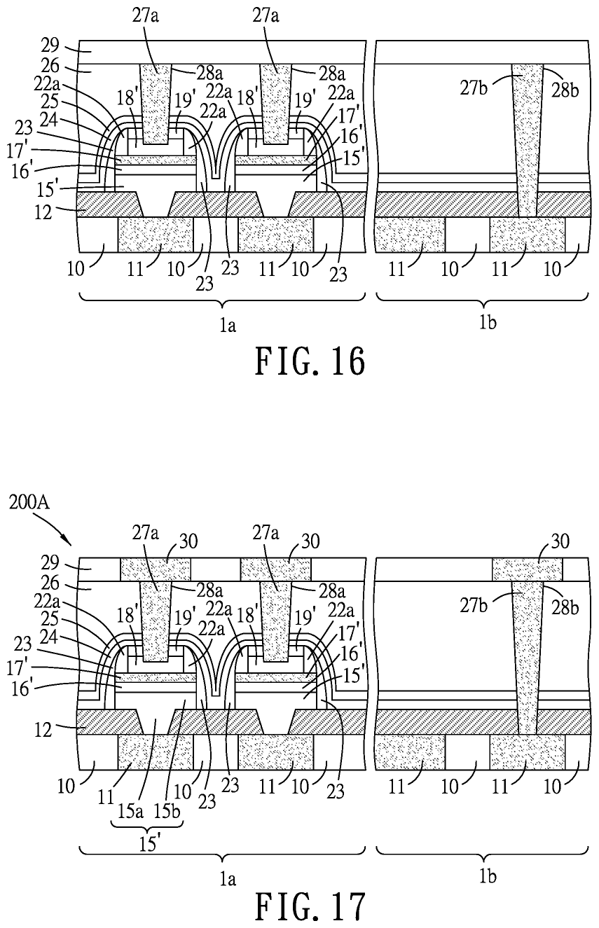

Referring to FIG. 1B and the example illustrated in FIG. 16, the method 100A then proceeds to step 115, where a third dielectric layer 29 is formed on the second dielectric layer 26 and the contact vias 27a, 27b. The material and process for forming the third dielectric layer 29 may be similar to or the same as those for forming the first dielectric layer 10 as described above in step 101, and thus details thereof are omitted for the sake of brevity.

Referring to FIG. 1B and the example illustrated in FIG. 17, the method 100A then proceeds to step 116, where a plurality of second metal lines 30 are formed in the third dielectric layer 29 such that the second metal lines 30 are respectively in electrical contact with the contact vias 27a, 27b. The material and process for forming the second metal lines 30 may be similar to or the same as those for forming the first metal lines 11 as described above in step 102, and thus details thereof are omitted for the sake of brevity. After this step, the semiconductor device 200A is obtained. In some embodiments, each of the ferroelectric elements 17′ may be referred to as a ferroelectric tunnel junction (FTJ) element. In some embodiments, each of the bottom electrodes 16′, a corresponding one of the ferroelectric elements 17′ and a corresponding one of the top electrodes 18′ may be collectively referred to as a ferroelectric capacitor. Each of the barriers 15′ has a cross section with a T shape, and includes a main portion 15a disposed in the first etch stop layer 12 and an upper portion 15b disposed on the main portion 15a and the first etch stop layer 12. The main portion 15a is formed integrally with the upper portion 15b. In some embodiments, the upper surface of the etch stop layer 12 is in contact with the upper portion 15b of the barrier 15′. In some embodiments, the main portion 15a of the barrier 15′ is tapered in a direction from the upper surface of the etch stop layer 12 to the lower surface of the etch stop layer 12.

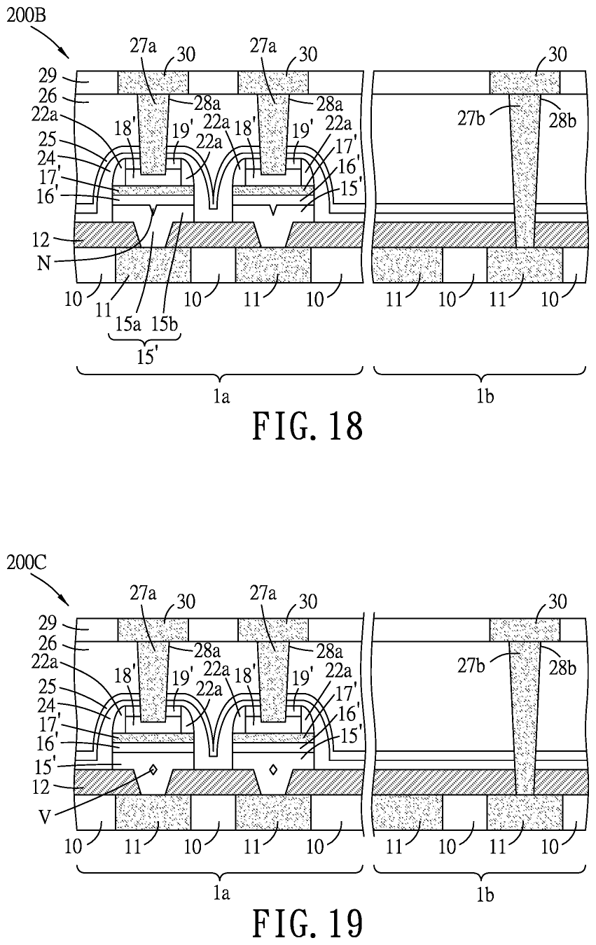

FIGS. 18 and 19 respectively illustrate schematic views of semiconductor devices 200B, 200C in accordance with some embodiments. The semiconductor device 200B is generally similar to the semiconductor device 200A, and a method for manufacturing the semiconductor device 200B is generally similar to the method 100A. As shown in FIG. 18, the semiconductor device 200B does not include the second spacers 23 (shown in FIG. 17), and the upper portion 15b of the barrier 15′ may be formed with a notch (N) that has a V-shaped cross section and the bottom electrode 16′ fills the notch (N). As shown in FIG. 19, the semiconductor device 200C does not include the second spacers 23, and a void (V) may be formed in the barrier 15′ and may have a cross section with a rhombus shape. There are no particular limitations on the number and shape of each of the notch (N) and the void (V). The notch (N) and the void (V) may be naturally formed in the barrier 15′ (e.g., in step 105) or may be formed due to process variations.

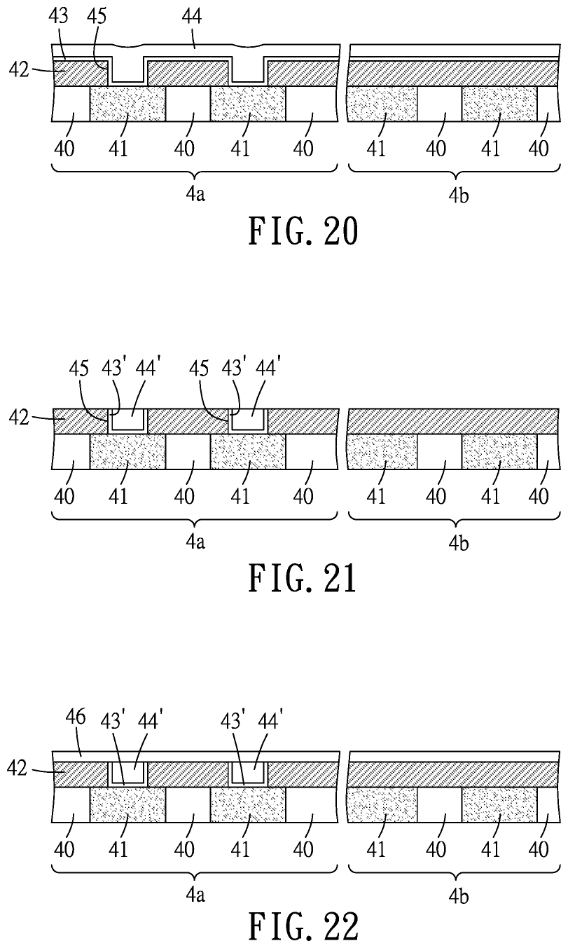

FIGS. 20 to 22 illustrate some intermediate steps of a method for manufacturing a semiconductor device (not shown). The semiconductor device is generally similar to the semiconductor device 200A. The intermediate steps shown in FIGS. 20 to 22 are generally similar to steps 101 to 106 of the method 100A.

As shown in FIG. 20, a semiconductor structure is provided. The semiconductor structure includes a dielectric layer 40, a plurality of metal lines 41, an etch stop layer 42, a barrier layer 43, and a via layer 44. In some embodiments, the semiconductor structure has a device memory region 4a, and a device peripheral region 4b. The metal lines 41 are formed in the dielectric layer 40 and are spaced apart from each other. The etch stop layer 42 is formed on the dielectric layer 40 and on the metal lines 41, and is formed with a plurality of openings 45 in the device memory region 4a. The barrier layer 43 is formed on an upper surface of the etch stop layer 42 and in the openings 45. The via layer 44 is formed on the barrier layer 43.

As shown in FIG. 21, a planarization process (e.g., (CMP)) is performed to remove an excess portion of the via layer 44 and an excess portion of the barrier layer 43 until the upper surface of the etch stop layer 42 is exposed, so as to form barriers 43′ and bottom vias 44′. Each of the bottom vias 44′ is separated from a corresponding one of the metal lines 41 and the etch stop layer 42 by a corresponding one of the barriers 43′.

As shown in FIG. 22, a bottom electrode layer 46 is formed on the upper surface of the etch stop layer 42, the barriers 43′ and the bottom vias 44′, followed by performing a planarization process (e.g., CMP) to remove an excess portion of the bottom electrode layer 46.

In the intermediate steps shown in FIGS. 20 to 22, the planarization processes are performed twice for respectively forming the barriers 43′ and the bottom vias 44′, followed by removing the excess portion of the bottom electrode layer 46. In steps 101 to 106 of the method 100A shown in FIGS. 2 to 7, the planarization process is performed only once to remove an excess portion of the bottom electrode layer 16. Therefore, the method 100A may provide a simplified process flow for manufacturing the semiconductor device 200A, and a manufacturing cost for manufacturing the semiconductor device 200A may be reduced.

In this disclosure, by sequentially forming a barrier layer and a bottom electrode layer, the planarization process is required to be performed only once for removing an excess portion of the bottom electrode layer. Therefore, a process flow for manufacturing a semiconductor device may be simplified, and a manufacturing cost for manufacturing semiconductor device may be reduced.

In accordance with some embodiments of the present disclosure, a semiconductor device includes an etch stop layer, a barrier, a bottom electrode, a ferroelectric element, and a top electrode. The barrier includes a main portion disposed in the etch stop layer and an upper portion disposed on the main portion and the etch stop layer. The bottom electrode is disposed on the upper portion of the barrier. The ferroelectric element is disposed on the bottom electrode opposite to the barrier. The top electrode is disposed on the ferroelectric element opposite to the bottom electrode.

In accordance with some embodiments of the present disclosure, the etch stop layer has an upper surface in contact with the upper portion of the barrier and a lower surface opposite to the upper surface, and the main portion of the barrier is tapered in a direction from the upper surface of the etch stop layer to the lower surface of the etch stop layer.

In accordance with some embodiments of the present disclosure, the bottom electrode has an upper flat surface on which the ferroelectric element is disposed.

In accordance with some embodiments of the present disclosure, the semiconductor device further includes a pair of spacers disposed on the ferroelectric element to laterally cover the top electrode.

In accordance with some embodiments of the present disclosure, the barrier has an upper surface formed with a notch and the bottom electrode fills the notch.

In accordance with some embodiments of the present disclosure, the barrier is formed with a void therein.

In accordance with some embodiments of the present disclosure, a method for manufacturing a semiconductor device includes: forming an etch stop layer with an opening; forming a barrier layer on the etch stop layer to fill the opening, the barrier layer including a layer portion disposed on the etch stop layer and an insert portion protruding from the layer portion so as to be inserted into the opening of the etch stop layer; forming a bottom electrode layer on the layer portion of the barrier layer opposite to the etch stop layer; forming a ferroelectric layer on the bottom electrode layer opposite to the barrier layer; and forming a top electrode layer on the ferroelectric layer opposite to the bottom electrode layer.

In accordance with some embodiments of the present disclosure, the method for manufacturing a semiconductor device further includes, before formation of the ferroelectric layer, planarizing the bottom electrode layer so as to permit the bottom electrode layer to be formed with an upper flat surface.

In accordance with some embodiments of the present disclosure, the etch stop layer has an upper surface in contact with the layer portion of the barrier layer and a lower surface opposite to the upper surface, and the insert portion of the barrier layer is formed with a tapered configuration which is tapered in a direction from the upper surface of the etch stop layer to the lower surface of the etch stop layer.

In accordance with some embodiments of the present disclosure, the method for manufacturing a semiconductor device further includes forming a mask layer on the top electrode layer.

In accordance with some embodiments of the present disclosure, the method for manufacturing a semiconductor device further includes patterning the mask layer and the top electrode layer so as to form the mask layer and the top electrode layer into a mask and a top electrode, respectively. The mask cooperates with the top electrode to form a stack.

In accordance with some embodiments of the present disclosure, the method for manufacturing a semiconductor device further includes forming a spacer layer to cover the ferroelectric layer and the stack.

In accordance with some embodiments of the present disclosure, the method for manufacturing a semiconductor device further includes etching the spacer layer so as to form the spacer layer into a pair of spacers disposed on the ferroelectric layer to cover two lateral sides of the stack.

In accordance with some embodiments of the present disclosure, the method for manufacturing a semiconductor device further includes, after formation of the spacers, etching the ferroelectric layer, the bottom electrode layer, and the barrier layer so as to form the ferroelectric layer, the bottom electrode layer, and the barrier layer into a ferroelectric element, a bottom electrode, and a barrier, respectively.

In accordance with some embodiments of the present disclosure, a method for manufacturing a semiconductor device includes: forming an interconnect structure on a semiconductor substrate, the interconnect structure including a dielectric layer and a conductive interconnect disposed in the dielectric layer; forming a first etch stop layer on the interconnect structure; forming on the first etch stop layer, a barrier layer which includes a layer portion disposed on the first etch stop layer and an insert portion protruding from the layer portion and penetrating the first etch stop layer so as to be connected to the conductive interconnect; forming a bottom electrode layer on the layer portion of the barrier layer opposite to the first etch stop layer; planarizing the bottom electrode layer; forming a ferroelectric layer on the bottom electrode layer opposite to the barrier layer; and forming a top electrode layer on the ferroelectric layer opposite to the bottom electrode layer.

In accordance with some embodiments of the present disclosure, the method for manufacturing a semiconductor device further includes, after formation of the first etch stop layer and before formation of the barrier layer, patterning the first etch stop layer so as to form an opening penetrating from an upper surface of the first etch stop layer to a lower surface of the first etch stop layer. The upper surface of the first etch stop layer is in contact with the layer portion of the barrier layer.

In accordance with some embodiments of the present disclosure, in formation of the barrier layer, the insert portion of the barrier layer is formed to fill the opening.

In accordance with some embodiments of the present disclosure, the opening has a dimension decreasing gradually in a direction from the upper surface of the first etch stop layer to the lower surface of the first etch stop layer, such that the insert portion of the barrier layer is formed with a tapered configuration.

In accordance with some embodiments of the present disclosure, after planarization of the bottom electrode layer, the bottom electrode layer is formed with an upper flat surface on which the ferroelectric layer is formed.

In accordance with some embodiments of the present disclosure, the method for manufacturing a semiconductor device further includes forming a mask layer on the top electrode layer opposite to the ferroelectric layer; patterning the mask layer and the top electrode layer so as to form the mask layer and the top electrode layer into a mask and a top electrode, respectively, the mask cooperating with the top electrode to form a stack; forming a spacer layer to cover the ferroelectric layer and the stack; sequentially etching the spacer layer, the ferroelectric layer, the bottom electrode layer, and the barrier layer, so as to form the spacer layer into a pair of first spacers, to form the ferroelectric layer into a ferroelectric element, to form the bottom electrode layer into a bottom electrode, and to form the barrier layer into a barrier, the pair of the first spacers being formed on the ferroelectric element to respectively cover two lateral sides of the stack; forming a pair of second spacers to cover the first spacers, two lateral sides of the ferroelectric element, two lateral sides of the bottom electrode, and two lateral sides of the barrier; forming a second etch stop layer on the first etch stop layer, the second spacers, and the mask; and forming a buffer layer over the second etch stop layer.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
an etch stop layer;
a barrier including a main portion disposed in the etch stop layer and an upper portion disposed on the main portion and the etch stop layer;
a bottom electrode disposed on the upper portion of the barrier;
a ferroelectric element disposed on the bottom electrode opposite to the barrier; and
a top electrode disposed on the ferroelectric element opposite to the bottom electrode.

2. The semiconductor device as claimed in claim 1, wherein the etch stop layer has an upper surface in contact with the upper portion of the barrier and a lower surface opposite to the upper surface, and the main portion of the barrier is tapered in a direction from the upper surface of the etch stop layer to the lower surface of the etch stop layer.

3. The semiconductor device as claimed in claim 1, wherein the bottom electrode has an upper flat surface on which the ferroelectric element is disposed.

4. The semiconductor device as claimed in claim 1, further comprising a pair of spacers disposed on the ferroelectric element to laterally cover the top electrode.

5. The semiconductor device as claimed in claim 1, wherein the barrier has an upper surface formed with a notch and the bottom electrode fills the notch.

6. The semiconductor device as claimed in claim 1, wherein the barrier is formed with a void therein.

7. A method for manufacturing a semiconductor device, comprising:
forming an etch stop layer with an opening;
forming a barrier layer on the etch stop layer to fill the opening, the barrier layer including a layer portion disposed on the etch stop layer and an insert portion protruding from the layer portion so as to be inserted into the opening of the etch stop layer;
forming a bottom electrode layer on the layer portion of the barrier layer opposite to the etch stop layer;
forming a ferroelectric layer on the bottom electrode layer opposite to the barrier layer; and
forming a top electrode layer on the ferroelectric layer opposite to the bottom electrode layer.

8. The method as claimed in claim 7, further comprising, before formation of the ferroelectric layer, planarizing the bottom electrode layer so as to permit the bottom electrode layer to be formed with an upper flat surface.

9. The method as claimed in claim 7, wherein
the etch stop layer has an upper surface in contact with the layer portion of the barrier layer and a lower surface opposite to the upper surface; and
the insert portion of the barrier layer is formed with a tapered configuration which is tapered in a direction from the upper surface of the etch stop layer to the lower surface of the etch stop layer.

10. The method as claimed in claim 7, further comprising forming a mask layer on the top electrode layer.

11. The method as claimed in claim 10, further comprising patterning the mask layer and the top electrode layer so as to form the mask layer and the top electrode layer into a mask and a top electrode, respectively, the mask cooperating with the top electrode to form a stack.

12. The method as claimed in claim 11, further comprising forming a spacer layer to cover the ferroelectric layer and the stack.

13. The method as claimed in claim 12, further comprising etching the spacer layer so as to form the spacer layer into a pair of spacers disposed on the ferroelectric layer to cover two lateral sides of the stack.

14. The method as claimed in claim 13, further comprising, after formation of the spacers, etching the ferroelectric layer, the bottom electrode layer, and the barrier layer so as to form the ferroelectric layer, the bottom electrode layer, and the barrier layer into a ferroelectric element, a bottom electrode, and a barrier, respectively.

15. A method for manufacturing a semiconductor device, comprising:
forming an interconnect structure on a semiconductor substrate, the interconnect structure including a dielectric layer and a conductive interconnect disposed in the dielectric layer;
forming a first etch stop layer on the interconnect structure;
forming on the first etch stop layer, a barrier layer which includes a layer portion disposed on the first etch stop layer and an insert portion protruding from the layer portion and penetrating the first etch stop layer so as to be connected to the conductive interconnect;
forming a bottom electrode layer on the layer portion of the barrier layer opposite to the first etch stop layer;
planarizing the bottom electrode layer;
forming a ferroelectric layer on the bottom electrode layer opposite to the barrier layer; and
forming a top electrode layer on the ferroelectric layer opposite to the bottom electrode layer.

16. The method as claimed in claim 15, further comprising, after formation of the first etch stop layer and before formation of the barrier layer, patterning the first etch stop layer so as to form an opening penetrating from an upper surface of the first etch stop layer to a lower surface of the first etch stop layer, the upper surface of the first etch stop layer being in contact with the layer portion of the barrier layer.

17. The method as claimed in claim 16, wherein in formation of the barrier layer, the insert portion of the barrier layer is formed to fill the opening.

18. The method as claimed in claim 17, wherein the opening has a dimension decreasing gradually in a direction from the upper surface of the first etch stop layer to the lower surface of the first etch stop layer, such that the insert portion of the barrier layer is formed with a tapered configuration.

19. The method as claimed in claim 15, wherein after planarization of the bottom electrode layer, the bottom electrode layer is formed with an upper flat surface on which the ferroelectric layer is formed.

20. The method as claimed in claim 15, further comprising:
forming a mask layer on the top electrode layer opposite to the ferroelectric layer;
patterning the mask layer and the top electrode layer so as to form the mask layer and the top electrode layer into a mask and a top electrode, respectively, the mask cooperating with the top electrode to form a stack;
forming a spacer layer to cover the ferroelectric layer and the stack;
sequentially etching the spacer layer, the ferroelectric layer, the bottom electrode layer, and the barrier layer, so as to form the spacer layer into a pairs of first spacers, to form the ferroelectric layer into a ferroelectric element, to form the bottom electrode layer into a bottom electrode, and to form the barrier layer into a barrier, the pair of the first spacers being formed on the ferroelectric element to respectively cover two lateral sides of the stack;
forming a pair of second spacers to cover the first spacers, two lateral sides of the ferroelectric element, two lateral sides of the bottom electrode, and two lateral sides of the barrier;
forming a second etch stop layer on the first etch stop layer, the second spacers, and the mask; and
forming a buffer layer over the second etch stop layer.
